(19) United States
(12) Patent Application Publication
(10) Pub. No.: US 2007/0228530 A1
(43) Pub. Date: Oct. 4, 2007

(54) Heat conductive bonding material, semiconductor package, heat spreader, semiconductor chip and bonding method of bonding semiconductor chip to heat spreader

(75) Inventors: Toshihisa Sato, Kawasaki (JP); Kenji Fukuzono, Kawasaki (JP); Masateru Koide, Kawasaki (JP)

Correspondence Address: ARENT FOX PLLC, 1050 CONNECTICUT AVENUE, N.W., SUITE 400, WASHINGTON, DC, 20036, US

(73) Assignee: FUJITSU LIMITED

(21) Appl. No.: 11/544,630

(22) Filed: Oct. 10, 2006

(30) Foreign Application Priority Data
Mar. 28, 2006 (JP) JP2006-086810

(51) Int. Cl. H01L 23/495

(52) U.S. Cl. 257/675

(57) ABSTRACT

A heat conductive bonding material 6 has a first bonding region 7 transferring heat of a semiconductor chip 1 to a heat spreader 4, and a second bonding region 8 relaxing a thermal stress generated between the semiconductor chip 1 and the heat spreader 4.

### BACKGROUND OF THE INVENTION

The present invention relates generally to a semiconductor device, and more particularly to a heat conductive bonding material, a semiconductor package, a heat spreader, a semiconductor chip and a bonding method of bonding the semiconductor chip to the heat spreader.

Over the recent years, mobile type electronic appliances have rapidly been developed. With this development, higher integration and down sizing/lighter-weight are demanded of the electronic appliances.

Known as a method of packaging the semiconductor chip onto a circuit board are a wire bonding method, a TAB (Tape Automated Bonding) method and a flip-chip method. According to the flip-chip method, connection terminals can be provided everywhere on the surface of the semiconductor chip. On the other hand, in the wire bonding method and the TAB method, the connection terminals can be provided only along the edge of the surface of the semiconductor chip. Generally, the semiconductor chip has an increased number of connection terminals when the integration of the circuit gets higher. Hence, the flip-chip method is capable of packaging the semiconductor chip exhibiting the higher integration onto the circuit board than by the wire bonding method and the TAB method. For these reasons, the semiconductor chip and the semiconductor package in the main stream are the semiconductor chip packaged by the flip-chip method and the semiconductor package thereof.

The following are the circuit boards each packaged with the semiconductor chip. To be specific, a conventional type of circuit board includes a single core layer composed of an epoxy resin, a glass cloth, etc and two wiring layers composed of copper foils etc, and is constructed so that the single core layer is sandwiched in between the two wiring layers. This circuit board is approximately 1.3 mm in thickness. In addition, the circuit board includes a wiring layer composed of the copper foil etc and an insulating layer made from an inter-layer insulating material such as a polyimide resin, and is constructed so that the wiring layers and the insulating layers are alternately stacked on each other in a sandwich like configuration. This thin type circuit board is approximately 0.1 mm through 0.4 mm in thickness. The thin type circuit board has none of the core layer and is therefore by far thinner in terms of the board thickness than the conventional type of circuit board. Accordingly, if using the thin type circuit board, it is possible to down size the electronic appliance and reduce a weight of the electronic appliance to a greater degree than using the conventional type of circuit board.

Moreover, technologies given in Patent document 1 and Patent document 2 are known as methods of bonding the respective components of the semiconductor package.

[Patent document 1] Japanese Patent application Laid-Open Publication No. 2001-185825

[Patent document 2] Japanese Patent application Laid-Open Publication No. 11-74431

### SUMMARY OF THE INVENTION

When the semiconductor chip is flip-chip-packaged onto the thin type circuit board on the basis of the prior arts described above, the following problems arise. This will hereinafter be described with reference to the drawings.

FIG. 5 is a sectional view of a semiconductor package (which will hereinafter be termed a testing sample) in which a semiconductor chip 101 is packaged on a thin type circuit board on the basis of a flip-chip method according to the prior art. An under surface of the semiconductor chip 101 is bonded to a thin type circuit board 104 via bump terminals 102 and an under fill material 103. With this structure, the circuit of the semiconductor chip 101 is electrically connected to the circuit of the thin type circuit board 104. On the other hand, an upper surface of the semiconductor chip 101 is bonded via a heat conductive bonding material 105 to a heat spreader 106. With this structure, heat of the semiconductor chip 101 is transferred to the heat spreader 106. Further, the thin type circuit board 104 is bonded to a stiffener 107 by a bonding agent 108. This intends to increase rigidity of the whole testing sample.

FIG. 6 is a sectional view illustrating a state where the testing sample is heated. The testing sample is heated when bonded by solder to a main board. Further, the semiconductor chip 101 emits the heat when performing an arithmetic process. When the testing sample reaches a high temperature, the thin type circuit board 104 thermally expands on the order of 30 ppm. On the other hand, the heat spreader 106 thermally expands on the order of only 15 through 20 ppm. This is because a material of which the thin type circuit board 104 is composed is resin, while a material of which the heat spreader 106 is composed is copper, stainless steel, etc. Accordingly, when the testing sample is heated, a thermal stress occurs in the semiconductor chip 101, the bump terminals 102, the under fill material 103 and the heat conductive bonding material 105, which are bonded between the thin type circuit board 104 and the heat spreader 106, due to a difference between a coefficient of thermal expansion of the thin type circuit board 104 and the coefficient of thermal expansion of the heat spreader 106. Moreover, a peripheral edge of the thin type circuit board 104 is fixed by the stiffener 107. The stiffener 107 is made from a material such as the copper and the stainless steel. Accordingly, it follows that the thermal stress of the heated thin type circuit board 104 acts in a direction orthogonal to the surface of the thin type circuit board 104. This thermal stress acting in the direction orthogonal to the surface of the thin type circuit board 104, it follows, acts in such a direction as to peel off the under fill material 103 bonded to the upper surface of the semiconductor chip 101 and the heat conductive bonding material 105 bonded to the under surface. In the case of a conventional type of board having a core layer, the core layer functions as a relaxant of the thermal stress acting in the direction orthogonal to the circuit board, and hence the thermal stress acting in such a direction as to perform peeling does not become much of the problem. In the case of the thin type circuit board having none of the core layer, however, the thermal stress acting in the direction orthogonal to the circuit board becomes large.

FIG. 7 is a sectional view showing in enlargement a bonding area between the semiconductor chip 101 and the heat spreader 106 of the testing sample. As described above, a tremendous quantity of thermal stress occurs on each of the components of the testing sample. Further, the heat conductive bonding material 105 is composed of the solder. The solder among the metallic materials is particularly low of yield point and is narrow of an elastically deformable range. Moreover, the heat conductive bonding material 105 has occurrence of a periodical thermal stress caused as a concomitant of repetitions of start and stop of an electronic appliance. Therefore, the heat conductive bonding material 105 comes to have a gradual accumulation of the plastic deformation as the thermal stress exceeding the breakdown point of the solder is periodically applied thereto. The heat conductive bonding material 105 suffers from occurrence of a crack (peeling) 109 when over a breaking load point.

A method of preventing the crack 109 from being caused in the heat conductive bonding material 105 involves a method of increasing a thickness of the heat conductive bonding material 105. If the heat conductive bonding material 105 is thickened, the thermal stress generated per unit thickness decreases. Accordingly, the thickness of the heat conductive bonding material 105 is increased to such a degree that the thermal stress occurred in the heat conductive bonding material 105 becomes equal to or lower than the breakdown point of the solder, whereby the crack 109 can be prevented from occurring. If the thickness of the heat conductive bonding material 105 is increased based on the prior art, the crack 109 does not occur, however, while on the other hand a quantity of the heat transferred to the heat spreader 106 from the semiconductor chip 101 decreases. This disables the semiconductor chip 101 from being sufficiently cooled down.

Such being the case, it is an object of the present invention to provide a heat conductive bonding material, a semiconductor package, a heat spreader, a semiconductor chip and a bonding method of bonding and the heat spreader together, which are capable of making compatible heat conductive performance and bonding reliability by bonding a semiconductor chip that is flip-chip-packaged onto a thin type circuit board and a heat spreader together.

To solve the above problem, the present invention adopts the following units in order to solve the problems. Namely, the present invention is a heat conductive bonding material comprising a first bonding region transferring heat of a semiconductor chip to a heat spreader, and a second bonding region relaxing a thermal stress generated between the semiconductor chip and the heat spreader.

According to the heat conductive bonding material described above, the heat conductive bonding material is provided with the second bonding region for relaxing the thermal stress of the heat conductive bonding material itself and is therefore hard to undergo occurrence of a crack. Further, the heat conductive bonding material is provided with the first bonding region that transfers the heat of the semiconductor chip to the heat spreader. Hence, the heat conductive bonding material according to the present invention is capable of making compatible the heat transfer performance and the bonding reliability even when bonding the semiconductor chip that is flip-chip-packaged onto the thin type circuit board and the heat spreader together. Herein, the first bonding region represents one region of the heat conductive bonding material and also represents the region performing a role of transferring, e.g., the heat of the semiconductor chip to the heat spreader. Moreover, the second bonding region represents one region of the heat conductive bonding material and also represents the region that relaxes the thermal stress generated in, e.g., the second bonding region itself.

Furthermore, the present invention is a semiconductor package that may comprise a semiconductor chip, a heat spreader, and a heat conductive bonding material including a first bonding region transferring heat of the semiconductor chip to the heat spreader, and a second bonding region relaxing a thermal stress generated between the semiconductor chip and the heat spreader, wherein the semiconductor chip may be bonded to the heat spreader by use of the heat conductive bonding material.

According to the semiconductor package described above, the heat conductive bonding material of this semiconductor package is hard to undergo the occurrence of the crack. Further, because of the high bonding reliability between the semiconductor chip and the heat spreader, there is no decrease in the heat transfer performance due to the occurrence of the crack. The heat transfer performance does not decrease, and hence the semiconductor chip within the semiconductor package is not overheated. It is therefore possible to provide the semiconductor package exhibiting a low rate of failure.

Moreover, the present invention is a heat spreader that may comprise a first bonding surface that is bonded to a first bonding region transferring heat of a semiconductor chip to the heat spreader, and a second bonding surface that is bonded to a second bonding region relaxing a thermal stress generated between the semiconductor chip and the heat spreader.

By the heat spreader described above, the first bonding region transferring the heat of the semiconductor chip to the heat spreader and the second bonding region relaxing the stress of the heat conductive bonding material via which the semiconductor chip are formed on the occasion of bonding the semiconductor chip and the heat spreader together. Hence, when the heat spreader according to the present invention is bonded to the semiconductor chip, the crack gets hard to occur in the bonding region. Therefore, the heat conductive bonding material according to the present invention is capable of making compatible the heat transfer performance and the bonding reliability even when bonding the semiconductor chip that is flip-chip-packaged onto the thin type circuit board and the heat spreader together. Herein, the first bonding surface represents a portion (surface) adjacent to the first bonding region and represents the surface for forming the first bonding region in the heat conductive bonding material when bonded to, e.g., the semiconductor chip. Further, the second bonding surface represents a portion (surface) adjacent to the second bonding region and represents the surface for forming the second bonding region in the heat conductive bonding material when bonded to, e.g., the semiconductor chip. It should be noted that if the second bonding surface exists in a position lower than the first bonding surface, the heat conductive bonding material is formed with the first bonding region and the second bonding region more surely.

Moreover, the present invention is a semiconductor chip that may comprise a third bonding surface that is bonded to a first bonding region transferring heat of the semiconductor chip to a heat spreader, and a fourth bonding surface that is bonded to a second bonding region relaxing a thermal stress generated between the semiconductor chip and the heat spreader.

According to the semiconductor chip described above, there are formed with the first bonding region transferring the heat of the semiconductor chip to the heat spreader and the second bonding region relaxing the stress of the heat conductive bonding material via which the semiconductor chip is bonded to the heat spreader on the occasion of bonding the semiconductor chip and the heat spreader together. Hence, when the semiconductor chip according to the present invention is bonded to the heat spreader, the crack gets hard to occur in the bonding region. Therefore, according to the semiconductor chip of the present invention, it is possible to make compatible the heat transfer performance and the bonding reliability even when bonding the semiconductor chip that is flip-chip-packaged onto the thin type circuit board and the heat spreader together. Herein, the third bonding surface represents a portion (surface) adjacent to the first bonding region and represents the surface for forming the first bonding region in the heat conductive bonding material when bonded to, e.g., the heat spreader. Further, the fourth bonding surface represents a portion (surface) adjacent to the second bonding region and represents the surface for forming the second bonding region in the heat conductive bonding material when bonded to, e.g., the heat spreader. It should be noted that if the fourth bonding surface exists in a position lower than the first bonding surface, the heat conductive bonding material is formed with the first bonding region and the second bonding region more surely.

Moreover, the present invention is a bonding method of bonding a semiconductor chip and a heat spreader together, which may comprise bonding a semiconductor chip to a heat spreader by use of a heat conductive bonding material including a first bonding region transferring heat of the semiconductor chip to the heat spreader, and a second bonding region relaxing a thermal stress generated between the semiconductor chip and the heat spreader.

According to the bonding method described above, the heat conductive bonding material, via which to bond the semiconductor chip and the heat spreader together, is formed with the first bonding region transferring the heat of the semiconductor chip to the heat spreader and with the second bonding region relaxing the stress of the heat conductive bonding material via which the semiconductor chip is bonded to the heat spreader. Hence, the crack gets hard to occur in the heat conductive bonding material. Therefore, according to the bonding method of the present invention, it is possible to make compatible the heat transfer performance and the bonding reliability even when bonding the semiconductor chip that is flip-chip-packaged onto the thin type circuit board and the heat spreader together.

According to the present invention, it is feasible to make compatible the heat transfer performance and the bonding reliability even when bonding the semiconductor chip that is flip-chip-packaged onto the thin type circuit board and the heat spreader together.

### BRIEF DESCRIPTION OF THE DRAWINGS

FIG. 1 is a sectional view showing in enlargement a bonding area between a semiconductor chip and a heat spreader of a semiconductor package according to a first embodiment;

FIG. 2 is a sectional view showing in enlargement the bonding area between the semiconductor chip and the heat spreader of the semiconductor package according to a second embodiment;

FIG. 3 is a sectional view showing in enlargement the bonding area between the semiconductor chip and the heat spreader of the semiconductor package according to a third embodiment;

FIG. 4 is a sectional view showing in enlargement the bonding area between the semiconductor chip and the heat spreader of the semiconductor package according to a fourth embodiment;

FIG. 5 is a view illustrating a semiconductor package in section according to the prior art;

FIG. 6 is a sectional view showing a state where the semiconductor package according to the prior art is heated;

FIG. 7 is a sectional view showing in enlargement the bonding area between the semiconductor chip and the heat spreader of the semiconductor package according to the prior art;

FIG. 8 is a view showing an analysis model used for analyzing in simulation a thermal stress occurred in the semiconductor package;

FIG. 9 is a table showing conditions in a simulation analysis model manufacturing step;

FIG. 10 is a table showing conditions of the respective simulation analysis models;

FIG. 11 is an equipressure contour representing a stress distribution of a tensile stress in a Z-axis direction, which occurs in a heat conductive bonding material;

FIG. 12 is a graph showing a stress distribution map that is plotted along an axis of Y═X;

FIG. 13 is a graph showing the stress distribution map that is plotted along an axis of Y=0;

FIG. 14 is a graph showing the maximum stress occurred in each analysis model; and

FIG. 15 is a table showing a result of a reliability test of an actual semiconductor package according to the first embodiment.

### DETAILED DESCRIPTION OF THE INVENTION

A best mode for carrying out the present invention will hereinafter be described in an exemplificative manner. Embodiments, which will be illustrated as below, are exemplifications, and the present invention is not limited to these exemplifications.

### First Embodiment

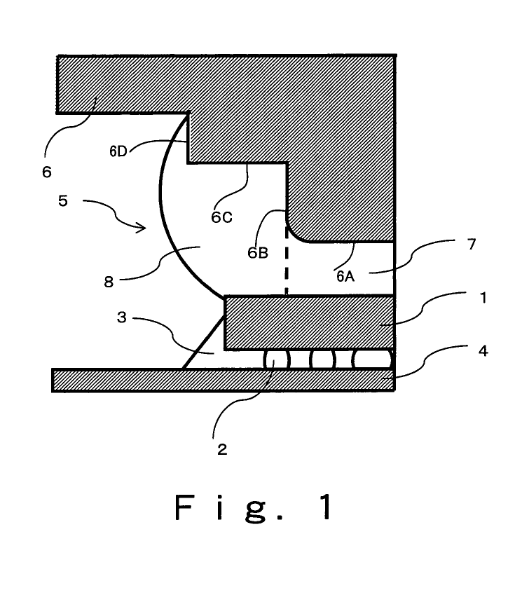

FIG. 1 is a sectional view showing in enlargement a bonding area between a semiconductor chip 1 and a heat spreader 6 of a semiconductor package according to a first embodiment. As shown in FIG. 1, the semiconductor package according to the first embodiment is constructed of a semiconductor chip 1, bump terminals 2, an under fill material 3, a thin type circuit board 4, a heat conductive bonding material 5 and a heat spreader 6. Further, the heat conductive bonding material 5 is constructed of a first bonding region 7 and a second bonding region 8.

The semiconductor chip 1 is an LSI (Large Scale Integrated circuit). The semiconductor chip 1 is packaged by a flip-chip technology onto the thin type circuit board 4 by use of the bump terminals 2 and the under fill material 3. FIG. 1 illustrates a case of providing one piece of semiconductor chip 1. The present invention is not, however, limited to this single chip type. Namely, a multi-chip type, in which the semiconductor chips are superposed on each other, may also be available.

The bump terminal 2 is a solder ball. The bump terminals 2 connect terminals of the semiconductor chip 1 to terminals of the thin type circuit board 4, respectively. FIG. 1 depicts a case of a solder bonding method. The bonding of the bump terminals 2 is not limited to the solder bonding method. Namely, there may be used a conductive paste bonding method and an Au bump thermal compression method. Moreover, FIG. 1 illustrates a BGA (Ball Grid Array) method that employs the solderballs. An LGA (Land GridArray) method mayalso, however, be available.

The under fill material 3 is a non-conductive synthetic resin. The under fill material 3 bonds the semiconductor chip 1 and the thin type circuit board 4 together by a flip-chi packaging method.

The thin type circuit board 4 is a coreless type of thin type circuit board built up by forming a plurality of sandwiched stacks of inter-layer insulating materials and wiring layers. The thin type circuit board 4 is 0.4 mm in thickness. The first embodiment exemplifies such a case that the circuit board is of the thin type. The present invention is not, however, limited to the thin type circuit board. Namely, a conventional type of circuit board may also be available if constructed to apply a larger thermal stress to the bonding area of the semiconductor chip and the heat spreader. Hence, the thickness of the thin type circuit board is not restricted to 0.4 mm.

The heat conductive bonding material 5 is composed of the solder. The heat conductive bonding material 5 bonds the semiconductor chip 1 to the heat spreader 6. Further, the heat conductive bonding material 5 is constructed of the first bonding region 7 and the second bonding region 8. The first embodiment exemplifies the case in which the heat conductive bonding material 5 is composed of the solder. The present invention is not, however, limited to the solder-based bonding material. Namely, the heat conductive bonding material may also be a heat conductive resin etc without being limited to the solder if enabling the crack to occur.

The heat spreader 6 is made from copper and stainless steel. The heat spreader 6 cools down the semiconductor package. FIG. 1 depicts an air cooling type heat spreader. The present invention is not, however, limited to the air-cooling type heat spreader. Namely, the heat spreader 6 may also be a water-cooling type heat spreader. Further, in FIG. 1, the heat spreader 6 is bonded directly to the semiconductor chip 1 by the heat conductive bonding material 5. The present invention is not, however, limited to this type of connection. Namely, an available mode may be such that a heat exchanger plate is sandwiched in between semiconductor chip 1 and the heat spreader 6.

As shown in FIG. 1, a first bonding surface 6A for bonding the first bonding region 7 and a second bonding surface 6C for bonding the second bonding region 8, are disposed on the under surface of the heat spreader 6 to which the semiconductor chip 1 is bonded. A stepped portion 6B is provided between the first bonding surface 6A and the second bonding surface 6C. Further, a stepped portion 6D is provided between the second bonding surface 6C and the under surface of the heat spreader 6. With these components, the under surface of the heat spreader 6 takes a configuration of having a 2-stepped protruded region constructed of the first bonding surface 6A, the stepped portion 6B, the second bonding surface 6C and the stepped portion 6D. The stepped portion 6B is provided between the first bonding surface 6A and the second bonding surface 6C, whereby on the occasion of bonding the semiconductor chip 1 and the heat spreader 6 together by use of the heat conductive bonding material 5, the heat conductive bonding material 5 is formed with the first bonding region 7 that transfers the heat of the semiconductor chip 1 to the heat spreader 6 and with the second bonding region 8 that relaxes the thermal stress generated between the semiconductor chip 1 and the heat spreader 6. Note that if constructed to provide a breadth equal to or larger than 0.5 mm between the stepped portion 6B and a side edge of the semiconductor chip 1, the thermal stress occurred in the heat conductive bonding material 5 is more relaxed than before. Moreover, if constructed to provide a width equal to or larger than 0.7 mm between the semiconductor chip 1 and the second bonding surface 6C, the thermal stress occurred in the heat conductive bonding material 5 is much more relaxed than before.

The first bonding region 7 is part of the heat conductive bonding material 5 described above. The first bonding region 7 mainly aims at transferring the heat of the semiconductor chip 1 to the heat spreader 6. The thickness of the first bonding region 7 is therefore restricted to a thickness to such a degree that the heat of the semiconductor chip 1 is sufficiently transferred to the heat spreader 6.

The second bonding region 8 is part of the heat conductive bonding material 5 described above. The second bonding region 8 mainly aims at relaxing the crack caused in the heat conductive bonding material 5. The second bonding region 8 therefore needs such a thickness that even the thermal stress generated due to the difference in the coefficient of thermal expansion between the semiconductor chip 1 and the heat spreader 6, does not exceed the breakdown point of the solder. In the first embodiment, the second bonding region 8 has the thickness that is equal to or larger than 0.7 mm. The present invention is not, however, limited to the thickness equal to or larger than this value. Namely, it may be sufficient that the second bonding region 8 has the thickness enabling the well relaxation of the thermal stress occurred due to the difference in the coefficient of thermal expansion between the semiconductor chip 1 and the heat spreader 6. Further, the second bonding region is constructed so that the breadth thereof becomes equal to or larger than 0.5 mm in an inward direction from the edge of the semiconductor chip 1. The present invention is not, however, limited to the breadth equal to or larger than this value. Namely, it may be sufficient that the second bonding region 8 has the breadth enabling the well relaxation of the thermal stress occurred due to the difference in the coefficient of thermal expansion between the semiconductor chip 1 and the heat spreader 6. Thus, the thickness of the second bonding region 8 is set greater than the thickness of the first bonding region 7, whereby the thermal stress generated per unit volume of the second bonding region 8 due to the heat emission from the semiconductor chip 1 is more relaxed than the thermal stress generated per unit volume of the first bonding region 7 due to the heat emission from the semiconductor chip 1. Moreover, the configuration in the first embodiment is that the second bonding region 8 embraces the side surface of the first bonding region 7. Namely, the second bonding region 8 embraces the outer peripheral edge of the first bonding region 7, whereby the heat conductive bonding material 5 is formed in a shape having a collar. This intends to prevent the occurrence of the crack that might be caused in the side surface of the heat conductive bonding material 5. The present invention is not, however, limited to this configuration. That is, the second bonding region is provided away from the first bonding region, whereby the two bonding regions may be made independent. Further, the second bonding region has no necessity of embracing the entire side surface of the first bonding region. Namely, the second bonding region relaxing the thermal stress may also be provided at a portion exhibiting a comparatively high possibility of causing the crack in the heat conductive bonding material.

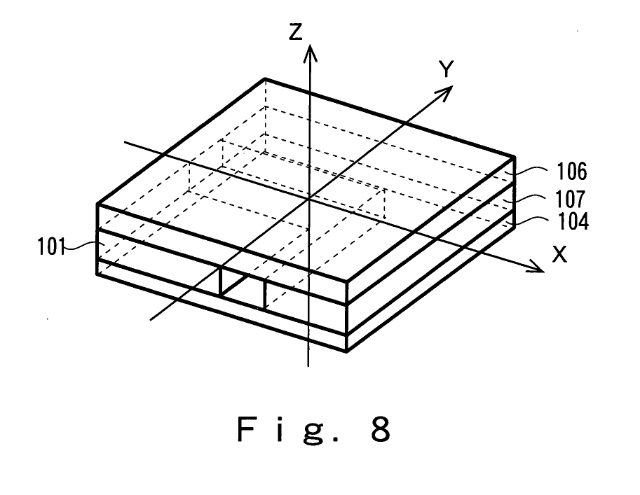

A result of analysis of the thermal stress generated in the semiconductor package in which the semiconductor chip 101 and the heat spreader 106 are bonded together by the heat conductive bonding material 105 on the basis of the prior art, will hereinafter be described with reference to FIGS. 8 through 13.

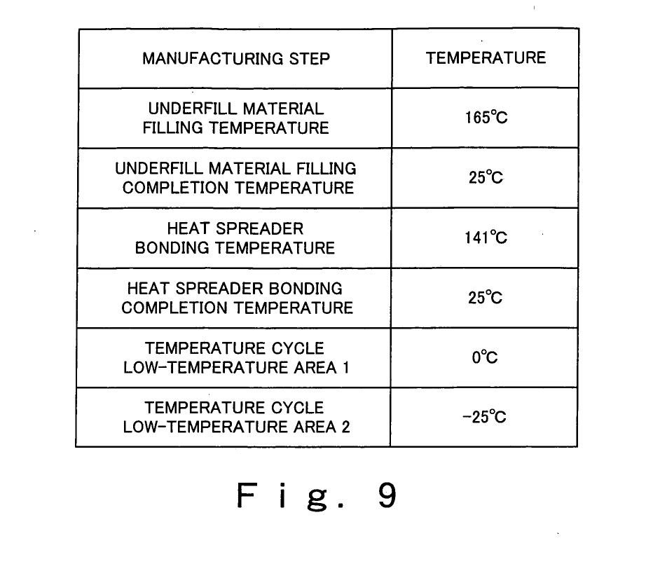

FIG. 8 illustrates an analysis model (a sample under test) for analyzing in simulation the thermal stress generated in the semiconductor package. The present simulation involves employing, as the analysis model, the semiconductor package including the semiconductor chip 101 taking a square shape that is 20 mm long in each of four sides as viewed from the upper surface. A premise is that the semiconductor chip 101 according to the analysis model be manufactured based on conditions shown in FIG. 9. Further, the simulation serves to analyze a stress distribution after an end of manufacturing the semiconductor package according to the conditions in FIG. 9. It is to be noted that when the semiconductor chip 101 emits the heat, the highest thermal stress, it is generally considered, occurs in the vicinity of an angular region (which will hereinafter be referred to as a corner region) of the upper surface of the semiconductor chip 101. Moreover, in the case of the square-shaped semiconductor chip 101, it is generally considered that the thermal stresses are distributed in symmetry with respect to a central point of the semiconductor chip 101. Therefore, the present simulation targets at the stress distribution on only one of four surfaces into which the (upper surface of) semiconductor chip 101 is divided equally by two lines extending through the center and orthogonal to each other.

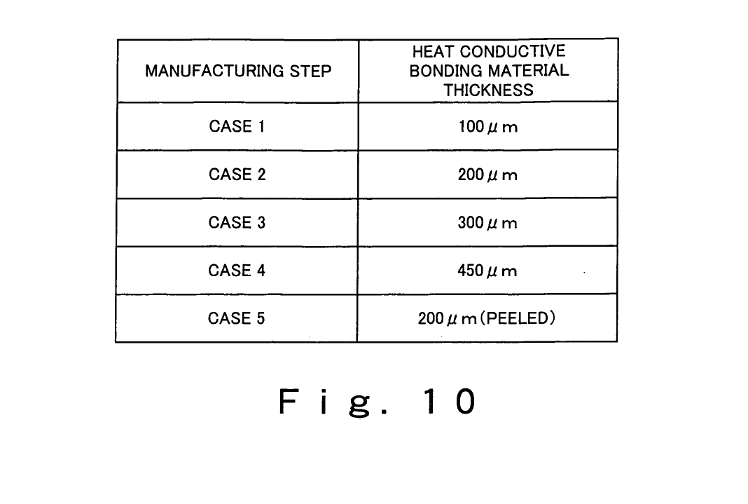

FIG. 10 shows simulation conditions (the thicknesses of the heat conductive bonding material 105) of the semiconductor package 101 according to the analysis model. Among five analysis models, cases 1 through 4 represent the analysis models in which the thicknesses of the heat conductive bonding material 5 are 100 μm, 200 μm, 300 μm and 450 μm. Further, a case 5 represents the analysis model in which the thickness of the heat conductive bonding material 5 is 200 μm and the corner region is in a state of its being peeled (a peeling length is 0.5 mm).

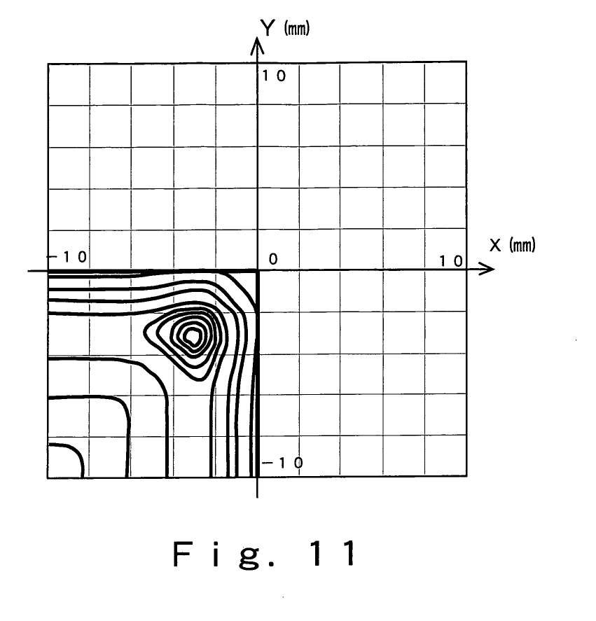

FIG. 11 visually illustrates, byway of a so-called equipressure contour, a stress distribution of a tensile stress in a Z-axis direction, which occurs in the heat conductive bonding material 105, in a case where the analysis model is manufactured based on the conditions shown in FIG. 9. The reason why the stress distribution as shown in FIG. 11 occurs lies in a difference in the coefficient of thermal expansion between the semiconductor chip 101 and the thin type circuit board 104.

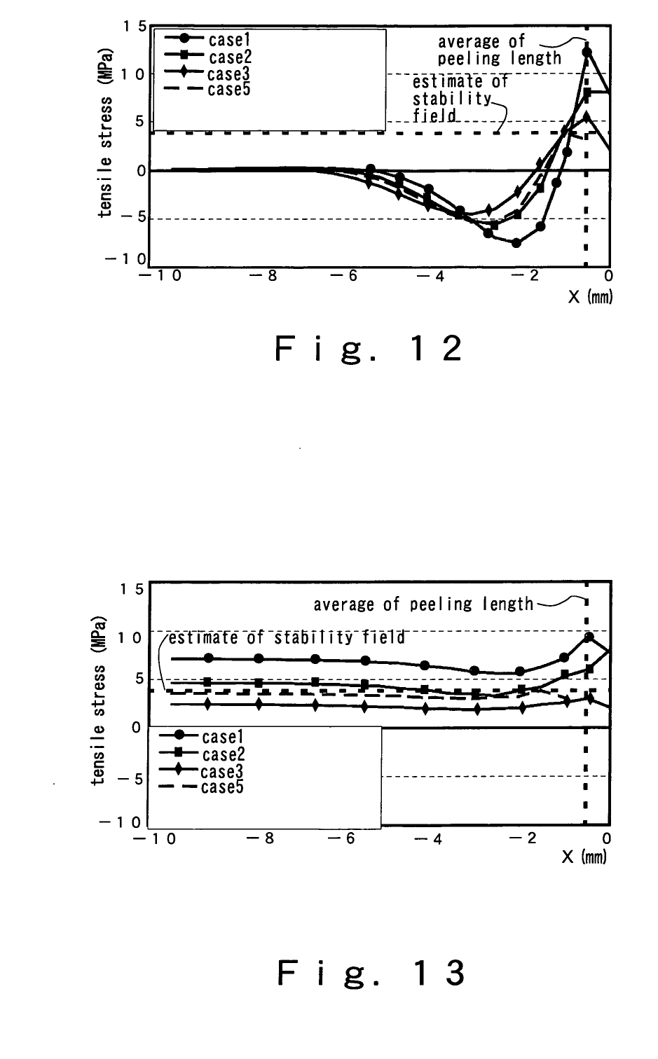

FIG. 12 is a graph, wherein the stress distribution map illustrated in FIG. 11 is plotted along an axis of Y═X. As shown in FIG. 12, according to the analysis simulation of the thermal stress, in the analysis models in relation to the cases 1 through 3 given above, the tensile stress abruptly decreases at a distance of 0.524 mm (X=−0.524: average peeling length) from the edge of the semiconductor chip 101. In other words, this means that the heat conductive bonding material 105 is peeled (cracked) to the length of 0.524 mm (X=−0.524) toward the center from the edge of the semiconductor chip 101. On the other hand, as shown by the analysis model of the case 5, the maximum stress occurred in the heat conductive bonding material 105 of which the corner region is peeled to a length of 0.5 mm, is estimated to be 3.84 MPa (an estimated stable area). Note that as shown in FIG. 12, the thermal stress in the vicinity (a left side in the graph) of the center of the semiconductor chip 101 is approximately 0 MPa. By contrast, a positive stress (the tensile stress) and a negative stress (a compressive stress) exist in intermixture in the vicinity (a right side in the graph) of the edge of the semiconductor chip 101. This implies that when the semiconductor chip 101 is flip-chip-packaged, the semiconductor chip 101 is warped in a convex shape. Further, the semiconductor chip 101 and the thin type circuit board 104 are bonded to the heat spreader 106 and the stiffener 107. Therefore, it follows that the portion vicinal to the edge of the semiconductor chip 101 is pressed against the heat spreader 106. Hence, this is because the compressive stress, it is considered, must have occurred in the vicinity of the edge of the semiconductor chip 101.

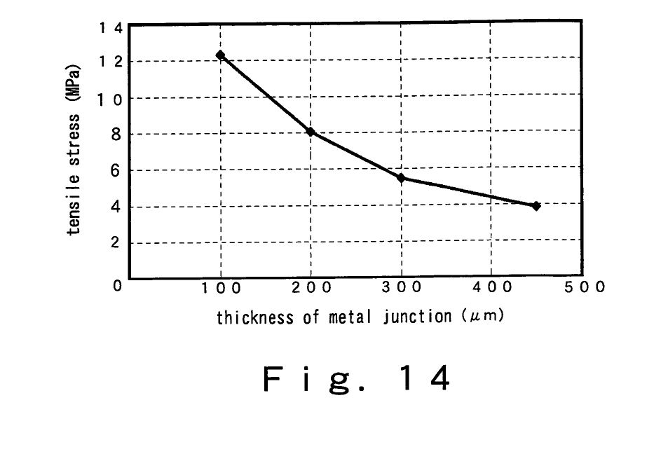

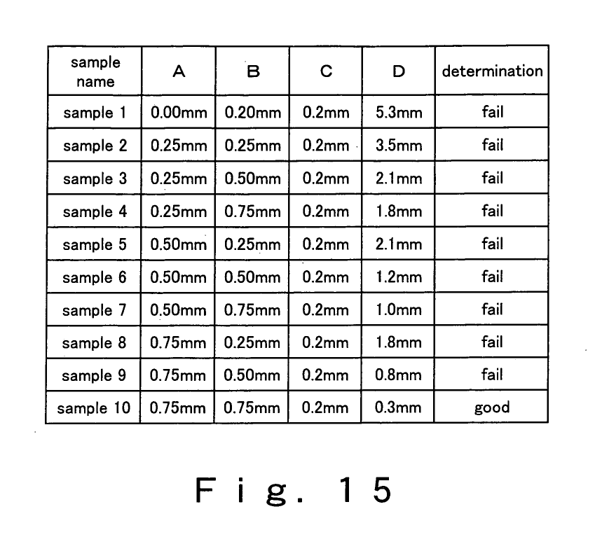

FIG. 13 is a graph in which the stress distribution map shown in FIG. 11 is plotted along an axis of Y=0. As explained above, the maximum stress occurred in the heat conductive bonding material 105 of which the corner region is peeled to the length of 0.5 mm, is estimated to be 3.84 MAP. Hence, as shown in FIG. 13, according to the analysis simulation of the thermal stress, the analysis model of the case 1 deviates from all the range of the estimated stable area. Accordingly, in the case of the analysis model of the case 1, it is presumed that all the periphery of the heat conductive bonding material 105 is peeled. Note that the peeling of the entire periphery is, it is confirmed, done in a test using an actual semiconductor package, about the case 1. Note that the stress distribution, it can be understood, exceeds the maximum stress in the vicinity of the right end if the graph, about the case 2. In fact, however, it is considered that the corner region of the semiconductor chip 110 is peeled, resulting in the occurrence of stress dispersion. Accordingly, a presumption is that the actual stress distribution gets approximate to the plotted distribution of the case 5. Incidentally, FIG. 14 is a graph showing the maximum stress occurred in each of the analysis models of the cases 1 through 4 described above.

It proves from the above that the stress causing the peeling of the heat conductive bonding material 105 has a fixed limit value. Further, it also proves that the tensile stress is relaxed according as thickness of the heat conductive bonding material 105 increases.

Given next as below is a result of a reliability test of the actual semiconductor package according to the first embodiment. FIG. 15 is a table showing the result of the reliabilitytest of the actualsemiconductor package. A symbol A shown in the table represents a distance from the edge of the semiconductor chip 1 to the first bonding region 7. In testing samples 1 through 10, the distance from the edge of the semiconductor chip 1 to the first bonding region 7 is changed stepwise. The distance from the edge of the semiconductor chip 1 to the first bonding region 7 is approximately the same as the breadth of the second bonding region 8 and is also approximately the same as the breadth of the second bonding surface 6C. A symbol B shown in the table represents a thickness of the first bonding region 7. The thickness of the first bonding region 7 is 0.2 mm in all the testing samples 1 through 10. This intends to sufficiently transfer the heat to the heat spreader 6 from the semiconductor chip 1. If the first bonding region 7 is larger than 0.2 mm in thickness, the heat from the semiconductor chip 1 is not sufficiently transferred to the heat spreader 6. The symbol C shown in the table represents a thickness of the second bonding region 8. In the testing samples 1 through 10, the thickness of the second bonding region 8 is changed stepwise. Note that the thickness of the second bonding region 8 of the testing sample 1 is the same as the thickness of the first bonding region 7. Namely, the testing sample 1 is the same as the semiconductor package based on the bonding method according to the prior art. A symbol C shown in the table represents a length of the peeling (the crack) occurred in the heat conductive bonding material 5. Note that the reliability test of the actual semiconductor package is based on a method of applying a 300-cycle thermal impact ranging from −10° C. to +100° C. to the semiconductor package. Further, a judgment result shown in the table is such that the testing sample is “good” if the peeling length is equal to or smaller than 0.7 mm but is “no good” if over 0.7 mm in terms of ensuring cooling performance of the semiconductor chip 1.

As the result of the reliability test of the actual semiconductor package on the basis of the thermal cycle described above, the distance from the edge of the semiconductor chip 1 to the first bonding region 7 is set on the order of about 1.0 mm, and the thickness of the second bonding region 8 is set on the order of about 0.75 mm, whereby it proves that the bonding reliability can be ensured by restraining the heat conductive bonding material 105 from being peeled while making sure of heat transfer capacity of the first bonding region that is needed for the heat radiation from the semiconductor chip 1.

### Second Embodiment

A modified example (which will hereinafter be referred to as a second embodiment) of the configuration of bonding the semiconductor chip and the heat spreader together. The first embodiment discussed above is the embodiment of providing the under surface of the heat spreader with the first bonding region mainly aiming at transferring the heat by forming the convex portion and the second bonding region mainly aiming at relaxing the thermal stress. The second embodiment provides the first bonding region mainly aiming at transferring the heat and the second bonding region mainly aiming at relaxing the thermal stress by forming a convex portion on the under surface of the heat spreader. As in the first embodiment discussed above, the following configuration is the exemplification, and the present invention is not limited to the configuration of the second embodiment.

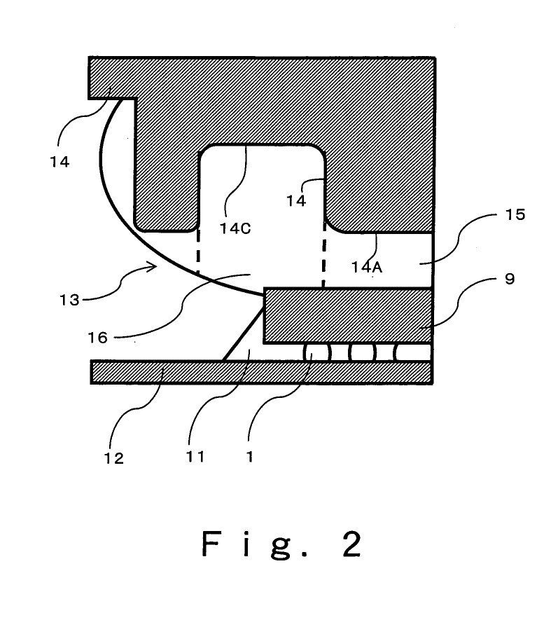

FIG. 2 is a sectional view showing a bonding configuration between the semiconductor chip and the heat spreader according to the second embodiment. As shown in FIG. 2, a heat spreader 14 has not the convex (protruded) bonding surface but a concave (recessed) surface. With this configuration, there are provided a first bonding region 15 mainly aiming at transferring the heat and a'second bonding region 16 mainly aiming at relaxing the thermal stress. Other configurations are the same as those in the first embodiment discussed above.

As illustrated in FIG. 2, the under surface of the heat spreader 14 to which a semiconductor chip 9 is bonded is provided with a concave (recessed) portion formed with a first bonding surface 14A that is bonded to first bonding region and a second bonding surface 14C that is bonded to the second bonding region. A step 14B is provided between the first bonding surface 14A and the second bonding surface 14C. The step 14B and the second bonding surface 14C are thus provided, thereby forming the first bonding region 15 that transfers the heat from the semiconductor chip 9 to the heat spreader 14 and the second bonding region 16 that relaxes the thermal stress occurred between the semiconductor chip 9 and the heat spreader 14 on the occasion of bonding the semiconductor chip 9 to the heat spreader 14 via a heat conductive bonding material 13. It is to be noted that if configured to provide a breadth equal to or larger than 0.5 mm between the step 14B and the edge of the semiconductor chip 9, the thermal stress occurred in the heat conductive bonding material 13 is more relaxed than before. Moreover, if configured to provide a breadth equal to or larger than 0.7 mm between the semiconductor chip 9 and the second bonding surface 14C, the thermal stress occurred in the heat conductive bonding material 13 is much more relaxed than before.

### Third Embodiment

A modified example (which will hereinafter be referred to as a third embodiment) of the bonding configuration between the semiconductor chip and the heat spreader, will hereinafter be shown. The first embodiment discussed above is the embodiment of providing the first bonding region mainly aiming at transferring the heat and the second bonding region mainly aiming at relaxing the thermal stress by forming the convex portion on the under surface of the heat spreader. The third embodiment provides the first bonding region mainly aiming at transferring the heat and the second bonding region mainly aiming at relaxing the thermal stress by forming a convex (protruded) portion taking a trapezoidal shape in section on the under surface of the heat spreader. As in the first embodiment discussed above, the following configuration is the exemplification, and the present invention is not limited to the configuration of the third embodiment.

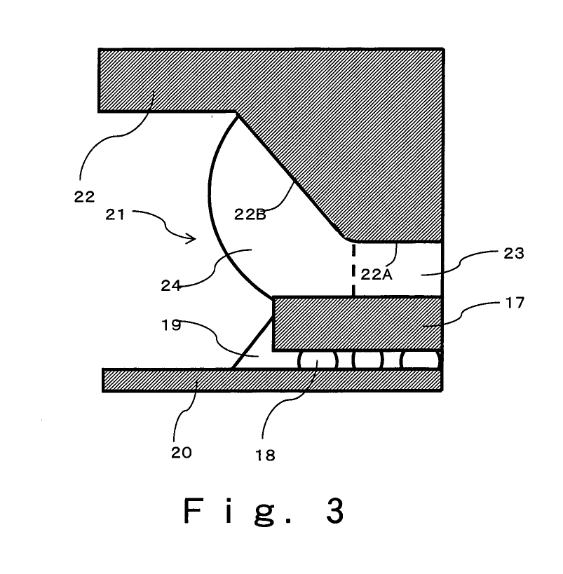

FIG. 3 is a sectional view showing the bonding configuration between the semiconductor chip and the heat spreader according to the third embodiment. As illustrated in FIG. 3, a heat spreader 21 according to the third embodiment has the convex (protruded) portion taking the trapezoidal shape insection on the under surface. With this configuration, there are provided a first bonding region 23 mainly aiming at transferring the heat and a second bonding region 24 mainly aiming at relaxing the thermal stress. Other configurations are the same as those in the first embodiment discussed above. Through this construction, the thermal stress is gradually relaxed in the second bonding region 24.

As shown in FIG. 3, the under surface of a heat spreader 22 to which a semiconductor chip 17 is bonded is provided with the convex (protruded) portion taking the trapezoidal shape in section, which is constructed of a first bonding surface 22A that is bonded to the first bonding region 23 and a second bonding surface 22B that is bonded to the second bonding region 24. A second bonding surface 22B having an oblique gradient is provided between a first bonding surface 22A and the under surface of the heat spreader 22. The second bonding surface 22B having the oblique gradient is thus provided, whereby a heat conductive bonding material 21 is formed with the first bonding region 23 transferring the heat of the semiconductor chip 17 to the heat spreader 22 and with the second bonding region 24 relaxing the thermal stress occurred between the semiconductor chip 17 and the heat spreader 22 on the occasion of bonding the semiconductor chip 17 and the heat spreader 22 together by use of the heat conductive bonding material 21. Further, the second bonding surface 22B has the oblique gradient, thereby providing a heat transfer function of transferring the heat of the semiconductor chip 17 to the heat spreader 22 and a stress relaxing function of relaxing the thermal stress generated between the semiconductor chip 17 and the heat spreader 22.

### Fourth Embodiment

A modified example (which will hereinafter be referred to as a fourth embodiment) of the bonding configuration between the semiconductor chip and the heat spreader, will hereinafter be shown. The first embodiment discussed above is the embodiment of providing the first bonding region mainly aiming at transferring the heat and the second bonding region mainly aiming at relaxing the thermal stress by forming the convex portion on the bonding surface of the heat spreader. The fourth embodiment is the embodiment of providing the first bonding region mainly aiming at transferring the heat and the second bonding region mainly aiming at relaxing the thermal stress by forming the semiconductor chip in a trapezoidal shape in section. As in the first embodiment discussed above, the following configuration is the exemplification, and the present invention is not limited to the configuration of the fourth embodiment.

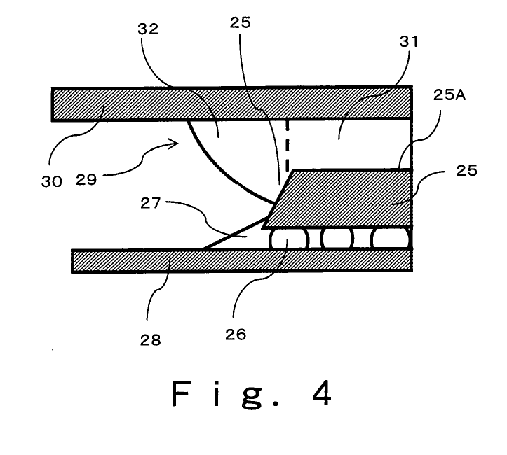

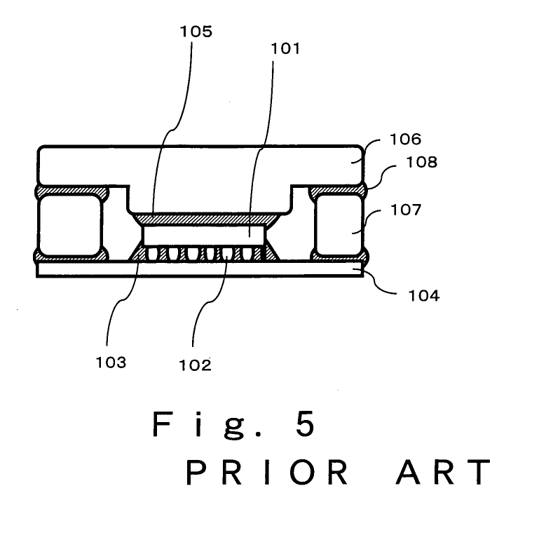

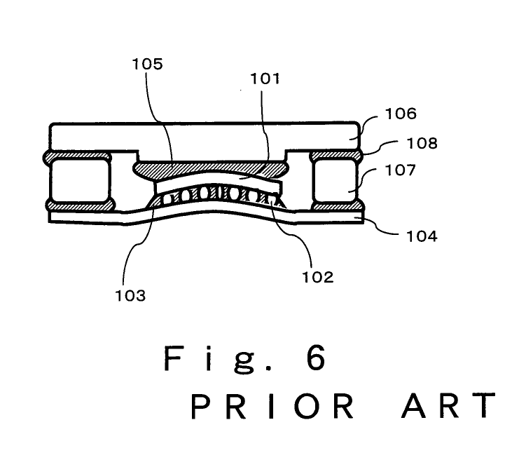

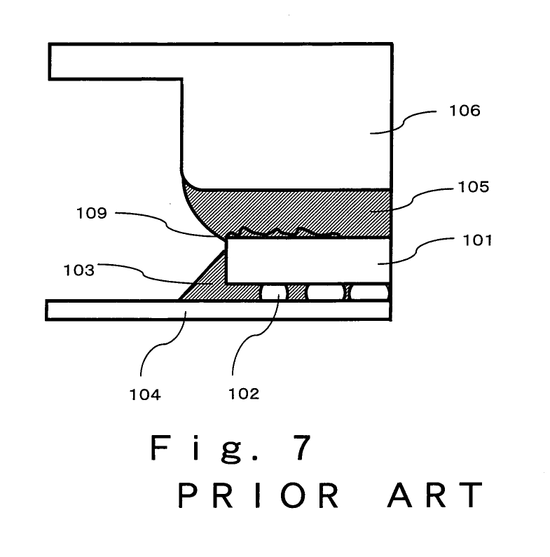

FIG. 4 is a sectional view showing the bonding configuration between the semiconductor chip and the heat spreader according to the fourth embodiment. As illustrated in FIG. 4, a semiconductor chip 25 according to the fourth embodiment takes the trapezoidal shape in section. With this configuration, there are provided a first bonding region 31 mainly aiming at transferring the heat and a second bonding region 32 mainly aiming at relaxing the thermal stress. Further, a heat spreader 30 has a flat under surface thereof. Other configurations are the same as those in the first embodiment discussed above. A thickness of the second bonding region 32 gradually changes, thereby gradually relaxing the thermal stress.

As depicted in FIG. 4, the upper surface of the semiconductor chip 25 to which the heat spreader 30 is bonded is defined as a third bonding surface 25A that is bonded to the first bonding region 31. Further, a side surface of the semiconductor chip 25 is defined as a fourth bonding surface 25B that is boned to the second bonding region 32. The third bonding surface 25A and the fourth bonding surface 25B are formed adjacently in a state of making an obtuse angle. The fourth bonding surface 25B having the oblique gradient is provided, whereby a heat conductive bonding material 29 is formed with the first bonding region 31 transferring the heat of the semiconductor chip 25 to the heat spreader 30 and with the second bonding region 32 relaxing the thermal stress generated between the semiconductor chip 25 and the heat spreader 30 on the occasion of bonding the semiconductor chip 25 and the heat spreader 30 together via the heat conductive bonding material 29. Moreover, the fourth bonding surface 25B has the oblique gradient, thereby providing the heat transfer function of transferring the heat of the semiconductor chip 25 to the heat spreader 30 and the stress relaxing function of relaxing the thermal stress generated between the semiconductor chip 25 and the heat spreader 30.

According to the first through fourth embodiments, it is possible to restrain the occurrence of the crack even when bonding the heat spreader to the semiconductor chip that is flip-chip-packaged onto the thin type circuit board. (0053] Further, the heat conductive bonding material, when the crack occurs, decreases in its heat conductive performance. This is because an air layer produced in a gap between the cracks has a low thermal conductivity. When the thermal conductivity of the heat conductive bonding material decreases, the heat of the semiconductor chip is not sufficiently transferred to the heat spreader. If the semiconductor chip is overheated, the integrated circuit and the bump terminals get melted. When the integrated circuit and the bump terminals get melted, with the result that the electronic circuit gets opened and short-circuited. When the electronic circuit gets opened and short-circuited, the testing sample does not function as the semiconductor package and falls into a failure. Accordingly, the failure of the semiconductor package due to the overheating of the semiconductor chip can be prevented on condition that the cracks caused in the heat conductive bonding material are reduced according to the present invention.

Further, the semiconductor package, in the case of an assembly type personal computer, might secondarily be manually bonded to the main board. In this case, there is a high possibility in which an excessive stress might be applied to between the semiconductor chip and the heat spreader. The present invention provides the high bonding reliability between the semiconductor chip and the heat spreader. Hence, the stress applied when secondarily bonding the semiconductor package to the main board etc enables the reduction of the cracks caused in the heat conductive bonding material. A probability of the failure of the semiconductor package mounted in the assembly type personal computer can be thereby decreased.

Moreover, on the occasion of the secondary bonding, the semiconductor package might be bonded to the main board by use of the solder. Herein, if soldered at a normal melting point, the semiconductor package reaches a high temperature, and hence the excessive thermal stress occurs in the bonding region between the semiconductor chip and the heat spreader. Accordingly, there is a possibility of causing the cracks in the heat conductive bonding area. Therefore, the semiconductor package might be secondarily bonded to the main board by employing the low-melting solder. In the case of the secondary bonding using the low-melting solder, however, the thermal stress generated by the heat emission from the semiconductor chip has a possibility of inducing the opening and the short-circuiting of the circuit in the bonding region. According to the present invention, the semiconductor chip can be secondarily bonded to the main board by employing the solder having the normal melting point because of the high bonding reliability between the semiconductor chip and the heat spreader. This enables the semiconductor package to be connected to the respective terminals of the main board with the high reliability.

Further, the semiconductor package might be mounted with a multiplicity of devices such as a fan for air-cooling. If a weight of the components mounted in the semiconductor package rises, the stress applied to the bonding region between the semiconductor chip and the heat spreader increases. Since the reliability of the bonding region is, however, higher than before, the present semiconductor package can be mounted with a greater number of devices than the semiconductor package based on the prior art.

### Others

The disclosures of Japanese patent application No. JP2006-086810 filed on Mar. 28, 2006 including the specification, drawings and abstract are incorporated herein by reference.

What is claimed is:

1. A heat conductive bonding material comprising:
a first bonding region transferring heat of a semiconductor chip to a heat spreader; and
a second bonding region relaxing a thermal stress generated between the semiconductor chip and the heat spreader.

2. A heat conductive bonding material according to claim 1, wherein the second bonding region is formed adjacently to a side surface of the first bonding region so as to cover the entire side surface of the first bonding region.

3. A heat conductive bonding material according to claim 1, wherein the second bonding region is formed so that its thickness in a direction perpendicular to a bonding surface between the semiconductor chip and the heat spreader is larger than that of the first bonding region.

4. A semiconductor package comprising:
a semiconductor chip;
a heat spreader; and
a heat conductive bonding material including a first bonding region transferring heat of the semiconductor chip to the heat spreader, and a second bonding region relaxing a thermal stress generated between the semiconductor chip and the heat spreader, wherein the semiconductor chip is bonded to the heat spreader by use of the heat conductive bonding material.

5. A semiconductor package according to claim 4, further comprising a thin type circuit board that is flip-chip-packaged onto the semiconductor chip.

6. A heat spreader comprising a first bonding surface that is bonded to a first bonding region transferring heat of a semiconductor chip to the heat spreader; and
a second bonding surface that is bonded to a second bonding region relaxing a thermal stress generated between the semiconductor chip and the heat spreader.

7. A heat spreader according to claim 6, wherein the second bonding surface is formed so as to embrace an outer edge of the first bonding surface.

8. A semiconductor chip comprising:
a third bonding surface that is bonded to a first bonding region transferring heat of the semiconductor chip to a heat spreader; and
a fourth bonding surface that is bonded to a second bonding region relaxing a thermal stress generated between the semiconductor chip and the heat spreader.

9. A semiconductor chip according to claim 8, wherein the fourth bonding surface is formed so as to embrace an outer edge of the third bonding surface.

10. A bonding method comprising:
bonding a semiconductor chip to a heat spreader by use of a heat conductive bonding material including a first bonding region transferring heat of the semiconductor chip to the heat spreader, and a second bonding region relaxing a thermal stress generated between the semiconductor chip and the heat spreader.
